(19) United States
(12) Patent Application Publication
(10) Pub. No.: US 2015/0348807 A1
(43) Pub. Date: Dec. 3, 2015

(54) ELECTRODE LAYER BENDING DEVICE FOR SENSING DEVICE

(71) Applicant: Primax Electronics Ltd., Taipei (TW)

(72) Inventors: CHONG HUANG, Taipei (TW); HE-MEI ZHU, Taipei (TW); WEI-FENG SUN, Taipei (TW)

(21) Appl. No.: 14/467,796

(22) Filed: Aug. 25, 2014

(30) Foreign Application Priority Data
May 27, 2014 (CN) 201410232443.3

(51) Int. Cl. H01L 21/67; H01L 21/683

(52) U.S. Cl. CPC H01L 21/67092; H01L 21/67138; H01L 21/6838

(57) ABSTRACT

An electrode layer bending device for a sensing device is provided. The electrode layer bending device includes an accommodation part, a pushing part, and a pressing part. The sensing part is accommodated within the accommodation part. The sensing device includes a first electrode layer and a second electrode layer. The second electrode layer has a wiring part. When the pushing part is driven to push the wiring part of the sensing device which is accommodated within the accommodation part, the wiring part is bent. When the pressing part is driven to press the bent wiring part, the wiring part is bent again and contacted with a first surface of the first electrode layer. Consequently, the electrical connection between the first electrode layer and the second electrode layer is established.

### FIELD OF THE INVENTION

The present invention relates to an electrode layer bending device, and more particularly to an electrode layer bending device for a sensing device.

### BACKGROUND OF THE INVENTION

With increasing development of science and technology, electronic apparatuses become more and more popular to personal users. The widely-used electronic apparatus includes for example a computer host, a notebook computer, a mobile phone or any other appropriate portable electronic apparatus. Generally, the electronic apparatus comprises a sensing device for performing sensing detection and implementing a corresponding function.

Hereinafter, the structure of a sensing device will be illustrated with reference to FIG. 1. FIG. 1 is a schematic exploded view illustrating the structure of a conventional sensing device. As shown in FIG. 1, the conventional sensing device 1 comprises a first electrode layer 11 and a second electrode layer 12. The first electrode layer 11 has plural first electrodes (not shown). The second electrode layer 12 and the first electrode layer 11 are stacked on each other. The second electrode layer 12 comprises plural second electrodes (not shown) and a wiring part 121. The wiring part 121 is connected with the plural second electrodes. Since the second electrode layer 12 and the first electrode layer 11 are connected with each other, the first electrodes of the first electrode layer 11 and the second electrodes of the second electrode layer 12 cannot be directly connected with each other. In particular, it is necessary to bend the wiring part 121 to allow the wiring part 121 to be connected with the first electrode layer 11. Consequently, the electrical connection between the first electrode layer 11 and the second electrode layer 12 may be established through the wiring part 121.

In accordance with the conventional technology, the wiring part 121 of the second electrode layer 12 is manually bent. The process of bending the wiring part 121 is time-consuming and the bending efficacy is usually unsatisfied. Moreover, since the second electrode layer 12 is a thin film made of polyvinylidene fluoride (PVDF) and with a film thickness of about 0.03 mm, the process of manually bending the wiring part 121 may easily damage the wiring part 121.

Therefore, there is a need of providing an electrode layer bending device for a sensing device in order to effectively bend the electrode layer.

### SUMMARY OF THE INVENTION

An object of the present invention provides an electrode layer bending device for a sensing device in order to effectively bend the electrode layer.

In accordance with an aspect of the present invention, there is provided an electrode layer bending device for establishing an electrical connection between a first electrode layer and a second electrode layer of a sensing device. The first electrode layer and the second electrode layer are stacked on each other. The second electrode layer includes an externally-extended wiring part. The electrode layer bending device includes a base, an accommodation part, a pushing part, and a pressing part. The accommodation part is formed in the base. The sensing device is accommodated within the accommodation part. The pushing part is located at a side of the accommodation part and inserted into the accommodation part so as to be contacted with the wiring part. When the pushing part is driven to push the wiring part, the wiring part is bent to be contacted with a lateral side of the first electrode layer, and a part of the bent wiring part is protruded outside the accommodation part. The pressing part is disposed on the base and located near the accommodation part. After the bent wiring part is pressed by the pressing part, the bent wiring part is bent again and contacted with a first surface of the first electrode layer, so that the electrical connection between the first electrode layer and the second electrode layer is established.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic exploded view illustrating the structure of a conventional sensing device;

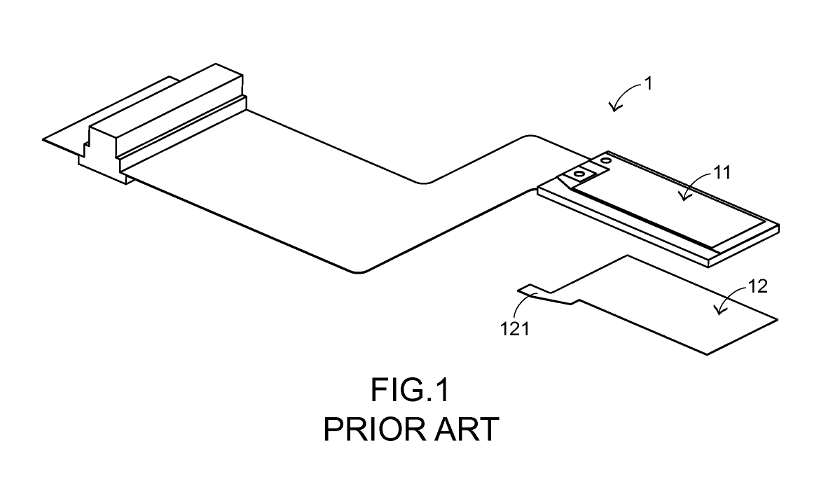

FIG. 2 is a schematic perspective view illustrating a sensing device to be bent by an electrode layer bending device according to an embodiment of the present invention, in which the sensing device is not bent;

FIG. 3 is a schematic perspective view illustrating the structure of the electrode layer bending device according to the embodiment of the present invention;

FIG. 4 is a schematic partial exploded view illustrating the structure of the electrode layer bending device of FIG. 3 and taken along another viewpoint;

FIG. 5 schematically illustrates the electrode layer bending device according to the embodiment of the present invention, in which the adhesive placement module is away from the accommodation part;

FIG. 6 schematically illustrates the electrode layer bending device according to the embodiment of the present invention, in which the adhesive placement module is near the accommodation part;

FIG. 7 schematically illustrates the electrode layer bending device according to the embodiment of the present invention, in which the pushing part is moved along a first vertical direction;

FIG. 8 schematically illustrates the electrode layer bending device according to the embodiment of the present invention, in which the pressing part is moved along a first horizontal direction; and

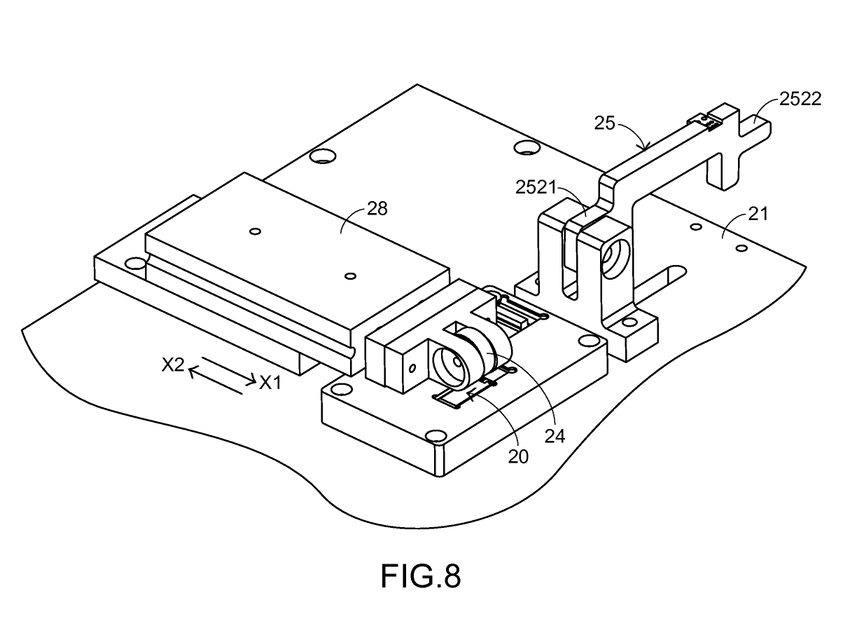

FIG. 9 is a schematic perspective view illustrating the sensing device after being bent by the electrode layer bending device according to the embodiment of the present invention.

### DETAILED DESCRIPTION OF THE PREFERRED EMBODIMENT

For obviating the drawbacks of the prior art technologies, the present invention provides an electrode layer bending device for a sensing device.

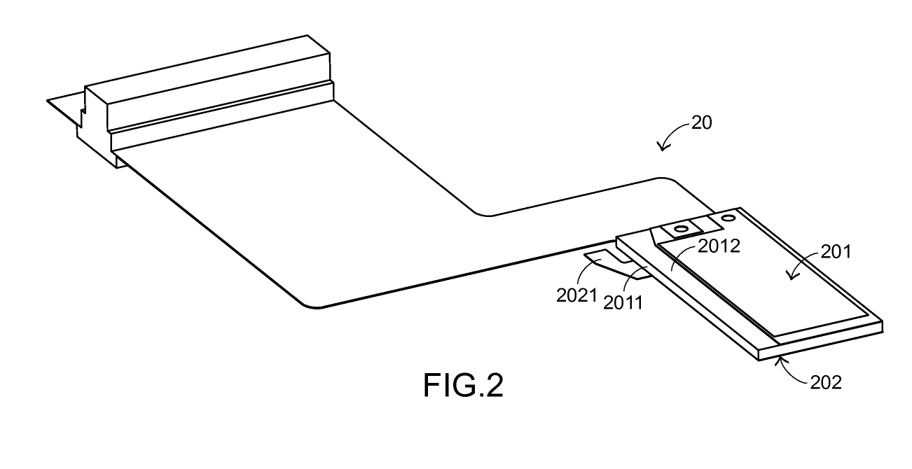

Hereinafter, a sensing device to be bent by the electrode layer bending device of the present invention will illustrated with reference to FIG. 2. FIG. 2 is a schematic perspective view illustrating a sensing device to be bent by an electrode layer bending device according to an embodiment of the present invention, in which the sensing device is not bent. As shown in FIG. 2, the sensing device 20 comprises a first electrode layer 201 and a second electrode layer 202. The first electrode layer 201 and the second electrode layer 202 are stacked on each other. The second electrode layer 202 comprises an externally-extended wiring part 2021. In an embodiment, the first electrode layer 201 is a thin film transistor (TFT). The second electrode layer 202 is made of polyvinylidene fluoride (PVDF), but is not limited thereto. Alternatively, in some other embodiments, the second electrode layer is made of polytetrafluoroethylene (PTFE), soluble polyfluoroalkoxy (PFA) or ethylene-tetra-fluoro-ethylene (FTFE).

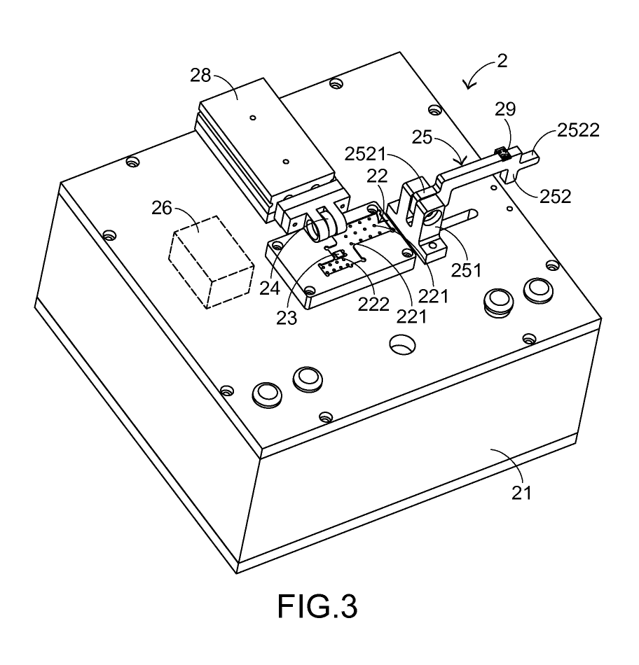

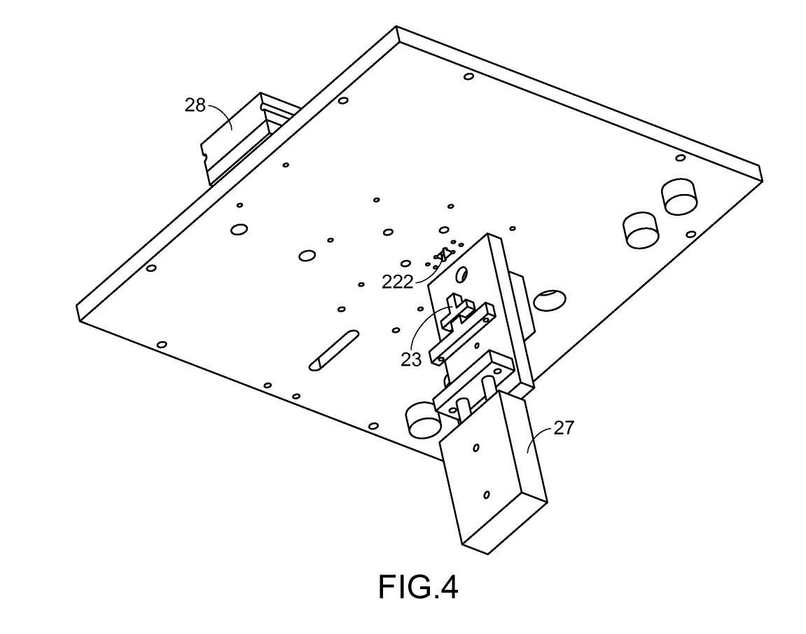

FIG. 3 is a schematic perspective view illustrating the structure of the electrode layer bending device according to the embodiment of the present invention. FIG. 4 is a schematic partial exploded view illustrating the structure of the electrode layer bending device of FIG. 3 and taken along another viewpoint. The electrode layer bending device 2 is used for establishing the electrical connection between the first electrode layer 201 and the second electrode layer 202 of the sensing device 20. The electrode layer bending device 2 comprises a base 21, an accommodation part 22, a pushing part 23, a pressing part 24, an adhesive placement module 25, an attracting module 26, a first driving part 27, and a second driving part 28. The accommodation part 22 is formed in the base 21 for accommodating the sensing device 20. The shape of the accommodation part 22 matches the outer profile of the sensing device 20. Moreover, plural first openings 221 and a second opening 222 are formed in the accommodation part 22. The plural first openings 221 are uniformly distributed in a bottom of the accommodation part 22. The second opening 222 is also formed in the bottom of the accommodation part 22. The pushing part 23 may be penetrated through the second opening 222. The pushing part 23 is disposed under the accommodation part 22. Moreover, the pushing part 23 is inserted into the accommodation part 22 and located at a side of the accommodation part 22. Consequently, when the sensing device 20 is accommodated within the accommodation part 22, the wiring part 2021 is located over the pushing part 23. After the pushing part 23 is penetrated through the second opening 222 and inserted into the accommodation part 22, the pushing part 23 is contacted with the wiring part 2021. Moreover, when the pushing part 23 is driven to push the wiring part 2021, the wiring part 2021 is bent.

Moreover, the pressing part 24 is placed on the base 21 and located near the accommodation part 22 for pressing the bent wiring part 2021. That is, by the pressing part 24, the bent wiring part 2021 is bent again. The first driving part 27 is disposed within the base 21 and connected with the pushing part 23 for providing a first motive power. In response to the first motive power, the pushing part 23 is moved relative to the accommodation part 22 along a first vertical direction Y1. Consequently, the pushing part 23 is moved along the first vertical direction Y1 to push the wiring part 2021. The second driving part 28 is disposed on the base 21 and connected with the pressing part 24 for providing a second motive power. In response to the second motive power, the pressing part 24 is rotated. Consequently, the pressing part 24 is moved relative to the accommodation part 22 along a first horizontal direction X1 to press the bent wiring part 2021. The attracting module 26 is disposed within the base 21 and located under the accommodation part 22 for producing an attracting force. When the sensing device 20 is attracted by the attracting force, the sensing device 20 is fixed in the accommodation part 22 without being detached from the accommodation part 22. In this embodiment, the pushing part 23 is a push rod, the pressing part 24 is a pressing roller, and the both of the first driving part 27 and the second driving part 28 are cylinder elements.

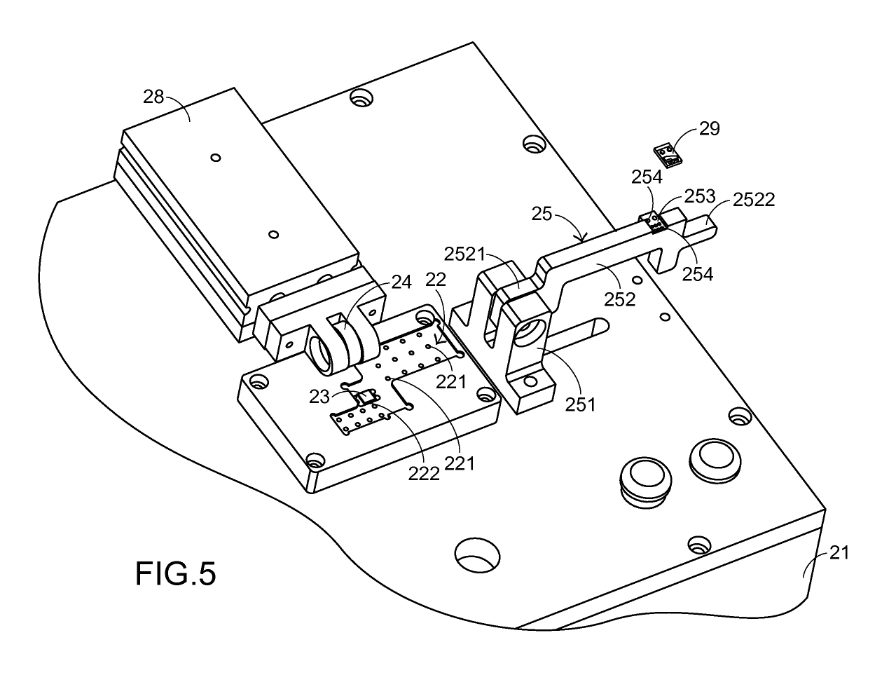

The structure of the adhesive placement module 25 will be illustrated as follows. FIG. 5 schematically illustrates the electrode layer bending device according to the embodiment of the present invention, in which the adhesive placement module is away from the accommodation part. The adhesive placement module 25 is disposed on the base 21 and connected with the attracting module 26. The adhesive placement module 25 is used for placing a pressure sensitive adhesive 29 on the wiring part 2021. In this embodiment, the adhesive placement module 25 comprises a supporting part 251, a swinging arm 252, a concave part 253, and plural third openings 254. The supporting part 251 is disposed on the base 21. A first end 2521 of the swinging arm 251 is connected with the supporting part 251. In addition, the swinging arm 252 may be swung relative to the base 21 by using the first end 2521 of the swinging arm 251 as a pivotal center. Consequently, the swinging arm 252 is swung toward the accommodation part 22 or swung away from the accommodation part 22. The concave part 253 is formed in the swinging arm 252, and located near a second end 2522 of the swinging arm 252. The pressure sensitive adhesive 29 may be received in the concave part 253. The plural third opening 254 are formed in the concave part 253 and connected with the attracting module 26. Since air is allowed to go through the third openings 254, the pressure sensitive adhesive 29 may be attracted by the attracting force and fixed in the concave part 253 without being detached from the concave part 253.

In an embodiment, the attracting module 26 comprises a vacuum generator and plural connection air pipes. For clarification and brevity, the vacuum generator and the plural connection air pipes are not shown in the drawings. The attracting module 26 is connected with the plural first openings 221 of the accommodation part 22 and the plural third openings 254 of the adhesive placement module 25 through the plural connection air pipes. Consequently, in response to the attracting force generated by the attracting module 26, the sensing device 20 and the pressure sensitive adhesive 29 are fixed by the accommodation part 22 and the adhesive placement module 25, respectively.

Hereinafter, the operations of the electrode layer bending device 2 will be illustrated with reference to FIGS. 3, 4 and 5. For establishing the electrical connection between the first electrode layer 201 and the second electrode layer 202 of the sensing device 20, the swinging arm 252 is firstly swung relative to the base 21 with the first end 2521 of the swinging arm 251 serving as the pivotal center, and the second end 2522 of the swinging arm 252 is swung away from the accommodation part 22. Meanwhile, the concave part 253 faces upwardly, and thus the pressure sensitive adhesive 29 can be placed in the concave part 253 (see FIG. 5). Then, the sensing device 20 is placed within the accommodation part 22, wherein the first electrode layer 201 faces the accommodation part 22 and the wiring part 2021 is disposed over the pushing part 23. Then, the attracting module 26 is enabled to generate an attracting force. In response to the attracting force, the air in the accommodation part 22 passes through the plural first openings 221. Consequently, the sensing device 20 is attracted by the attracting force and fixed in the accommodation part 22. Moreover, in response to the attracting force, the air in the concave part 253 passes through the plural third openings 254, so that the pressure sensitive adhesive 29 is attracted by the attracting force and fixed in the concave part 253.

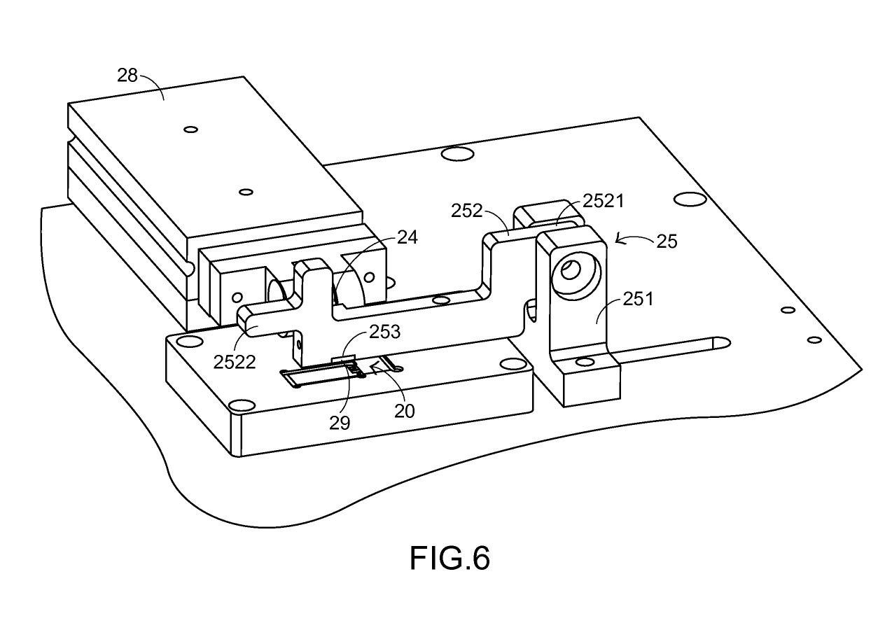

The attracting module 26 continuously generates the attracting force. In addition, the swinging arm 252 is swung relative to the base 21 with the first end 2521 of the swinging arm 251 serving as the pivotal center, and the second end 2522 of the swinging arm 252 is swung toward the accommodation part 22 (see FIG. 6). Under this circumstance, the pressure sensitive adhesive 29 in the concave structure 253 is contacted with the wiring part 2021. Then, the attracting module 26 stops generating the attracting force. Consequently, the pressure sensitive adhesive 29 is detached from the concave structure 253 and placed on the wiring part 2021. Then, the swinging arm 252 is swung relative to the base 21 with the first end 2521 of the swinging arm 251 serving as the pivotal center, and the second end 2522 of the swinging arm 252 is swung away from the accommodation part 22 again. Consequently, the subsequent operations are not hindered by the second end 2522 of the swinging arm 252.

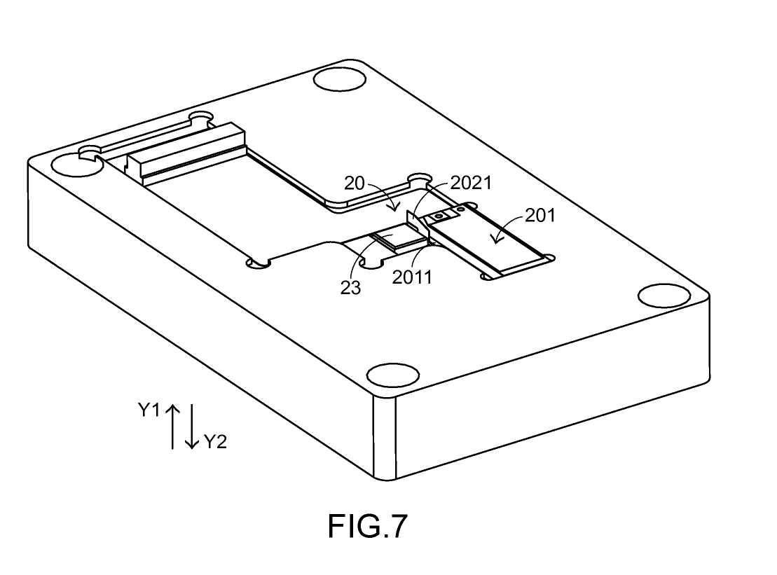

After the second end 2522 of the swinging arm 252 is away from the accommodation part 22, the first driving part 27 is controlled to drive the pushing part 23. Consequently, the pushing part 23, which is penetrated through the second opening 222, is moved relative to the accommodation part 22 along the first vertical direction Y1 so as to push the wiring part 2021. Meanwhile, the wiring part 2021 is pushed and bent by the pushing part 23. The bent pushing part 23 is contacted with a lateral side 2011 of the first electrode layer 201. At the same time, a part of the bent wiring part 2021 is protruded outside the accommodation part 22. The location of the pushing part 23 and the status of the bent wiring part 2021 are shown in FIG. 7. After the wiring part 2021 is bent and a part of the bent wiring part 2021 is protruded outside the accommodation part 22, the first driving part 27 is controlled to drive the pushing part 23 again. Consequently, the pushing part 23 is moved relative to the accommodation part 22 along the second vertical direction Y2, and the wiring part 2021 is no longer pushed by the pushing part 23.

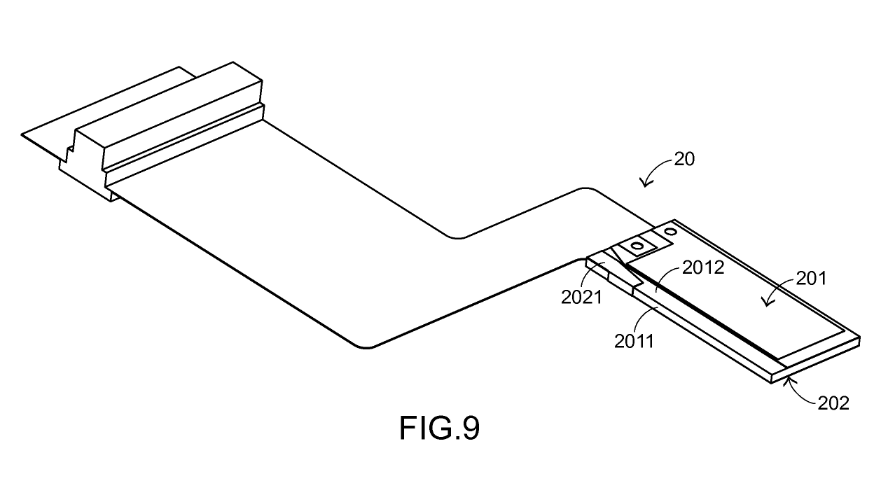

Then, the second driving part 28 is controlled to drive the pressing part 24. Consequently, the pressing part 24 is moved relative to the accommodation part 22 along the first horizontal direction X1 to press the part of the bent wiring part 2021 that is protruded outside the accommodation part 22. Under this circumstance, the bent wiring part 2021 is bent again and contacted with a first surface 2012 of the first electrode layer 201. While the pressing part 24 is moved along the first horizontal direction X1 and rotated to press the bent wiring part 2021, the pressure sensitive adhesive 29 on the first electrode layer 201 produces an adhesive property in response to a pressing force of the pressing part 24. Due to the adhesive property, the wiring part 2021 is adhered on the first surface 2012 of the first electrode layer 201. Under this circumstance, the electrical connection between the first electrode layer 201 and the second electrode layer 202 is established (see FIG. 9).

Then, the second driving part 28 is controlled to drive the pressing part 24 again. Consequently, the pressing part 24 is moved along the second vertical direction X2, and the bent wiring part 2021 is no longer pressed by the pressing part 24. Under this circumstance, the electrical connection between the first electrode layer 201 and the second electrode layer 202 is completely established.

The following two aspects should be specially described. Firstly, in this embodiment, the procedure of swinging the swinging arm 252 is manually performed by the worker. It is noted that numerous modifications and variations may be made while retaining the teachings of the present invention. For example, in another embodiment, the electrode layer bending device further comprises a third driving part. The third driving part is disposed on the supporting part and connected with the swinging arm for providing a third motive power. In response to the third motive power, the second end of the swinging arm is swung relative to the base to be near the accommodation part or away from the accommodation part. The third driving part may be controlled through a corresponding operating button or an operating interface.

Secondly, the controlling mechanisms of the first driving part 27 and the second driving part 28 are similar to the control mechanism of the third driving part. That is, the first driving part 27 and the second driving part 28 may be controlled through the corresponding operating buttons or the operating interface. In other words, the swinging action of the swinging arm 252, the movement of the pushing part 23 and the rotation and the movement of the pressing part 24 may be manually performed, but are not limited thereto. Alternatively, in another embodiment, a controlling unit is installed in the electrode layer bending device of the present invention. The time points of enabling the first driving part 27, the second driving part 28 and the third driving part are previously set by the controlling unit. Consequently, the operation process of the electrode layer bending device may be automatically performed without the manual operation. Similarly, the procedure of placing the sensing device 20 in the accommodation part 22 and the procedure of placing the pressure sensitive adhesive 29 in the concave part 253 may be manually performed or automatically performed by robotic arms or exclusive fixtures.

From the above descriptions, the present invention provides an electrode layer bending device for a sensing device. After the sensing device is accommodated within an accommodation part, a wiring part of a second electrode layer is pushed by a pushing part. Consequently, the wiring part is bent by the pushing part, and the bent wiring part is contacted with a lateral side of a first electrode layer. Then, the bent wiring part is pressed by a pressing part, and the wiring part is bent again and contacted with a first surface of the first electrode layer. Consequently, the electrical connection between the first electrode layer and the second electrode layer is established. Moreover, during the process of bending the wiring part, the bent wiring part is contacted with lateral side of the first electrode layer. Consequently, the wiring part can be effectively bent. Similarly, during the process of bending the wiring part again, the bent wiring part is contacted with the first surface of the first electrode layer. Consequently, the wiring part can be also effectively bent. In comparison with the conventional technology, the electrode layer bending device of the present invention is capable of effectively bending the wiring part without the need of manually bending the wiring part. Consequently, the possibility of damaging the wiring part is minimized.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An electrode layer bending device for establishing an electrical connection between a first electrode layer and a second electrode layer of a sensing device, the first electrode layer and the second electrode layer being stacked on each other, the second electrode layer comprising an externally-extended wiring part, the electrode layer bending device comprising:
a base;
an accommodation part formed in the base, wherein the sensing device is accommodated within the accommodation part;
a pushing part located at a side of the accommodation part and inserted into the accommodation part so as to be contacted with the wiring part, wherein when the pushing part is driven to push the wiring part, the wiring part is bent to be contacted with a lateral side of the first electrode layer, and a part of the bent wiring part is protruded outside the accommodation part; and
a pressing part disposed on the base and located near the accommodation part, wherein after the bent wiring part is pressed by the pressing part, the bent wiring part is bent again and contacted with a first surface of the first electrode layer, so that the electrical connection between the first electrode layer and the second electrode layer is established.

2. The electrode layer bending device according to claim 1, further comprising an attracting module, wherein the attracting module is disposed within the base and located under the accommodation part, wherein the attracting module generates an attracting force, and the sensing device is attracted by the attracting force and fixed in the accommodation part.

3. The electrode layer bending device according to claim 2, wherein the accommodation part further comprise plural first openings, and the plural first openings are formed in a bottom of the accommodation part, wherein air is allowed to go through the plural first openings, so that the sensing device is attracted by the attracting force.

4. The electrode layer bending device according to claim 2, further comprising an adhesive placement module, wherein the adhesive placement module is placed on the base and connected with a vacuum generator of the attracting module, and a pressure sensitive adhesive is placed on the wiring part through the adhesive placement module, wherein the adhesive placement module comprises:
a supporting part disposed on the base;
a swinging arm, wherein a first end of the swinging arm is connected with the supporting part, and the swinging arm is swung relative to the base, so that the swinging arm is swung near the accommodation part or away from the accommodation part;
a concave part formed in the swinging arm and located near a second end of the swinging arm, wherein the pressure sensitive adhesive is received in the concave part; and
plural second openings formed in the concave part and connected with the vacuum generator, wherein air is allowed to go through the plural second openings, so that the pressure sensitive adhesive is attracted by the attracting force and fixed in the concave part,
wherein when the sensing device is accommodated within the accommodation part and the second end of the swinging arm is swung relative to the base to be near the accommodation part, the pressure sensitive adhesive in the concave part is contacted with the wiring part, wherein after the vacuum generator stops generating the attracting force, the pressure sensitive adhesive is detached from concave part and placed on the wiring part.

5. The electrode layer bending device according to claim 4, further comprising a first driving part, wherein the first driving part is disposed within the supporting part and connected with the swinging arm, and provides a first motive power, wherein in response to the first motive power, the second end of the swinging arm is selectively swung relative to the base to be near the accommodation part or away from the accommodation part.

6. The electrode layer bending device according to claim 1, further comprising a second driving part, wherein the second driving part is disposed within the base and connected with the pushing part, and provides a second motive power, wherein in response to the second motive power, the pushing part is moved relative to the accommodation part along a first vertical direction so as to push the wiring part, wherein after the wiring part is bent and contacted with the lateral side of the first electrode layer, the pushing part is moved relative to the accommodation part along a second vertical direction in response to the second motive power provided by the second driving part, so that the pushing part stops pushing the wiring part.

7. The electrode layer bending device according to claim 1, further comprising a third driving part, wherein the third driving part is disposed on the base and connected with the pressing part, and provides a third motive power, wherein in response to the third motive power, the pressing part is rotated, and the pressing part is moved relative to the accommodation part along a first horizontal direction to press the bent wiring part, wherein after the bent wiring part is bent and contacted with the first surface of the first electrode layer, the pressing part is moved relative to the accommodation part along a second horizontal direction in response to the third motive power provided by the third driving part, so that the pressing part stops pressing the bent wiring part.

8. The electrode layer bending device according to claim 1, wherein while the pressing part is rotated to press the bent wiring part, a pressure sensitive adhesive on the wiring part produces an adhesive property in response to a pressure of the pressing part, wherein according to the adhesive property, the wiring part is adhered on the first surface of the first electrode layer.

9. The electrode layer bending device according to claim 1, wherein the first electrode layer is a thin film transistor (TFT).

10. The electrode layer bending device according to claim 1, wherein the second electrode layer is made of polyvinylidene fluoride (PVDF), polytetrafluoroethylene (PTFE), soluble polyfluoroalkoxy (PFA) or ethylene-tetra-fluoro-ethylene (FTFE).
